(19) United States
(12) Patent Application Publication
(10) Pub. No.: US 2022/0216304 A1
(43) Pub. Date: Jul. 7, 2022

(54) III-NITRIDE TRANSISTOR WITH NON-UNIFORM CHANNEL REGIONS

(71) Applicant: Cambridge Electronics, Inc., Cambridge, MA (US)

(72) Inventor: Bin Lu, Fremont, CA (US)

(21) Appl. No.: 17/562,164

(22) Filed: Dec. 27, 2021

Related U.S. Application Data
(60) Provisional application No. 63/133,396, filed on Jan. 3, 2021.

(51) Int. Cl. H01L 29/10; H01L 29/45; H01L 29/20; H01L 29/778; H01L 29/47; H01L 29/66; H01L 29/06; H01L 29/423; H01L 29/417

(52) U.S. Cl. CPC H01L 29/1029; H01L 29/452; H01L 29/2003; H01L 29/7786; H01L 29/41775; H01L 29/66462; H01L 29/0607; H01L 29/42316; H01L 29/475

(57) ABSTRACT

This disclosure describes the structure and technology to modify the distribution of channel electron density underneath the gate electrode of III-nitride semiconductor transistors. Electron density reduction regions (EDR regions) are disposed in the gate region of the transistor structure. In certain embodiments, the EDR regions are created using recesses. In other embodiments, the EDR regions are created by implanting the regions with a species that reduces the free electrons in the channel layer. In another embodiment, the EDR regions are created by forming a cap layer over the barrier layer, wherein the cap layer reduces the free electrons in the channel beneath the cap layer. The gate electrode may make Schottky contact with the barrier layer and the EDR regions, or a dielectric layer may be disposed in the gate region.

This application claims priority of U.S. Provisional Patent Application Ser. No. 63/133,396, filed Jan. 3, 2021, the disclosure of which is incorporated herein in its entirety.

### FIELD

Embodiments of the present disclosure relate to transistor structures and methods for forming these transistor structures.

### BACKGROUND

Compared with conventional power devices made of silicon, Group III-Nitride (III-N) semiconductors possess excellent electronic properties that enable the fabrication of modern power electronic devices and structures for use in a variety of applications. The limited critical electric field and relatively high resistance of silicon make currently available commercial power devices, circuits and systems constrained with respect to operating frequencies. On the other hand, the higher critical electric field and higher electron density and mobility of III-N materials allow high-current, high-voltage, high-power and/or high-frequency performance of improved power transistors. These attributes are desirable in advanced transportation systems, high-efficiency electricity generation and conversion systems, and energy delivery networks. Such systems rely on efficient power converters to modify electric voltages, and use power transistors capable of blocking large voltages and/or carrying large currents. For example, power transistors with blocking voltages of more than 500V are used in hybrid vehicles to convert DC power from the batteries to AC power. Some other exemplary applications of power transistors include power supplies, automotive electronics, automated factory equipment, motor controls, traction motor drives, high voltage direct current (HVDC) electronics, lamp ballasts, telecommunication circuits and display drives.

Conventional III-nitride semiconductor transistors have a uniform electron density in the channel underneath the gate.

It would be beneficial if there were a transistor structure with non-uniform electron density in the channel region underneath the gate. Further, it would be advantageous if the non-uniform electron density distribution improved transistor linearity.

### SUMMARY

This disclosure describes the structure and technology to modify the distribution of channel electron density underneath the gate electrode of III-nitride semiconductor transistors. Electron density reduction regions (EDR regions) are disposed in the gate region of the transistor structure. In certain embodiments, the EDR regions are created using recesses. In other embodiments, the EDR regions are created by implanting the regions with a species that reduces the free electrons in the channel layer. In another embodiment, the EDR regions are created by forming a cap layer over the barrier layer, wherein the cap layer reduces the free electrons in the channel beneath the cap layer. The gate electrode may make Schottky contact with the barrier layer and the EDR regions, or a dielectric layer may be disposed in the gate region.

According to one embodiment, a semiconductor structure for use in a III-Nitride (III-N) semiconductor device is disclosed. The semiconductor structure comprises a channel layer; a barrier layer, wherein electrons are formed at an interface between the channel layer and the barrier layer; a source contact and a drain contact disposed in ohmic recesses in contact with the barrier layer; a gate electrode disposed between the source contact and the drain contact, wherein a region under the gate electrode comprises a gate region; and one or more electron density reduction regions disposed in the gate region, wherein electron density in the electron density reduction regions is reduced as compared to other portions of the gate region, wherein the electron density reduction regions comprise a cap layer disposed on the barrier layer, and wherein the cap layer is not disposed on the barrier layer in the other portions of the gate region, and the cap layer comprises a Mg-doped III-nitride semiconductor. In some embodiments, each electron density reduction region has a length (La) and a width (Wa), and is separated from an adjacent electron reduction region by a separation distance (Wb), wherein a ratio of Wb/(Wa+Wb) is between 0.05 and 0.95. In some embodiments, the gate electrode makes Schottky contact with a top surface of the barrier layer and a top surface of the cap layer. In some embodiments, the semiconductor structure comprises a dielectric layer disposed on a top surface of the cap layer in the gate region; wherein the gate electrode makes Schottky contact with a top surface of the barrier layer and contacts a top surface of the dielectric layer. In some embodiments, the dielectric layer comprises SiO₂, SiₓN_{y}, SiOₓN_{y}, Al₂O₃ or a combination thereof. In some embodiments, the semiconductor structure comprises a gate dielectric layer disposed on a top surface of the barrier layer and on a top surface of the cap layer in the gate region; wherein the gate electrode contacts the gate dielectric layer. In some embodiments, the gate dielectric layer comprises SiO₂, SiₓN_{y}, SiOₓN_{y}, Al₂O₃, HfO₂ or a combination thereof. In some embodiments, the semiconductor structure comprises a gate dielectric layer disposed on a top surface of the barrier layer and on a top surface of the dielectric layer in the gate region; wherein the gate electrode contacts the gate dielectric layer. In some embodiments, the gate dielectric layer comprises SiO₂, SiₓN_{y}, SiOₓN_{y}, Al₂O₃, HfO₂ or a combination thereof.

According to another embodiment, a semiconductor structure for use in a III-Nitride (III-N) semiconductor device is disclosed. The semiconductor structure comprises a channel layer; a barrier layer, wherein electrons are formed at an interface between the channel layer and the barrier layer; a source contact and a drain contact disposed in ohmic recesses in contact with the barrier layer; a gate electrode disposed between the source contact and the drain contact, wherein a region under the gate electrode comprises a gate region; one or more electron density reduction regions disposed in the gate region, wherein electron density in the electron density reduction regions is reduced as compared to other portions of the gate region; wherein the electron density reduction regions comprise implanted regions in the barrier layer, wherein a depth of the implanted region is less than, the same as, or greater than a thickness of the barrier layer. In some embodiments, the implanted regions are implanted with hydrogen, nitrogen, argon, fluorine, or magnesium. In some embodiments, the gate electrode makes Schottky contact with a top surface of the barrier layer and a top surface of the implanted regions. In some embodiments, the semiconductor structure comprises a dielectric layer disposed on a top surface of the implanted regions in the gate region; wherein the gate electrode makes Schottky contact with a top surface of the barrier layer and contacts the dielectric layer above the implanted regions. In some embodiments, the semiconductor structure comprises a gate dielectric layer disposed on a top surface of the barrier layer and on a top surface of the implanted regions in the gate region; wherein the gate electrode contacts the gate dielectric layer. In some embodiments, the gate dielectric layer comprises SiO₂, SiₓN_{y}, SiOₓN_{y}, Al₂O₃, HfO₂ or a combination thereof.

According to another embodiment, a semiconductor structure for use in a III-Nitride (III-N) semiconductor device is disclosed. The semiconductor structure comprises a channel layer; a barrier layer, wherein electrons are formed at an interface between the channel layer and the barrier layer; a source contact and a drain contact disposed in ohmic recesses in contact with the barrier layer; a gate electrode disposed between the source contact and the drain contact, wherein a region under the gate electrode comprises a gate region; and one or more electron density reduction regions disposed in the gate region, wherein electron density in the electron density reduction regions is reduced as compared to other portions of the gate region; wherein the electron density reduction regions comprise recesses wherein a depth of the recesses is less than, the same as, or greater than a thickness of the barrier layer. In some embodiments, the gate electrode makes Schottky contact with a top surface of the barrier layer and a top surface of the recesses. In some embodiments, the semiconductor structure comprises a dielectric layer disposed on a top surface of the recesses in the gate region; wherein the gate electrode makes Schottky contact with a top surface of the barrier layer and contacts the dielectric layer above the recesses. In some embodiments, the semiconductor structure comprises a gate dielectric layer disposed on a top surface of the barrier layer and on a top surface of the recesses in the gate region; wherein the gate electrode contacts the gate dielectric layer. In some embodiments, the gate dielectric layer comprises SiO₂, SiₓN_{y}, SiOₓN_{y}, Al₂O₃, HfO₂ or a combination thereof.

### BRIEF DESCRIPTION OF THE FIGURES

For a better understanding of the present disclosure, reference is made to the accompanying drawings, which are incorporated herein by reference and in which:

FIG. 1A is a top view of a transistor structure according to one embodiment;

FIG. 1B is a cross-section of the transistor structure of FIG. 1A taken along line A-A′;

FIG. 1C is a cross-section of the transistor structure of FIG. 1A along line C-C′ in which the EDR regions comprise a cap layer;

FIG. 1D is a cross-section of the transistor structure of FIG. 1A along line C-C′ wherein the electron reduction region is an implanted region;

FIG. 1E is a cross-section of the transistor structure of FIG. 1A along line C-C′ wherein the electron reduction region is recreated by recesses;

FIGS. 2A-2C are cross-sections of the transistor structure of FIG. 1A along line B-B′ according to different embodiments, where the EDR regions are as shown in FIG. 1C;

FIGS. 2D-2F are cross-sections of the transistor structure of FIG. 1A along line B-B′ according to different embodiments, where the EDR regions are as shown in FIG. 1D

FIGS. 2G-2I are cross-sections of the transistor structure of FIG. 1A along line B-B′ according to different embodiments, where the EDR regions are as shown in FIG. 1E; and

FIG. 3 shows a flowchart that shows the processes for making the embodiments described herein.

### DETAILED DESCRIPTION

Embodiments of the present disclosure describe the structure and technology to modify the distribution of channel electron density underneath the gate. The semiconductor structures described herein may be formed of compound semiconductor materials, such as III-V semiconductor materials, and particularly Group III-Nitride (III-N) semiconductor materials.

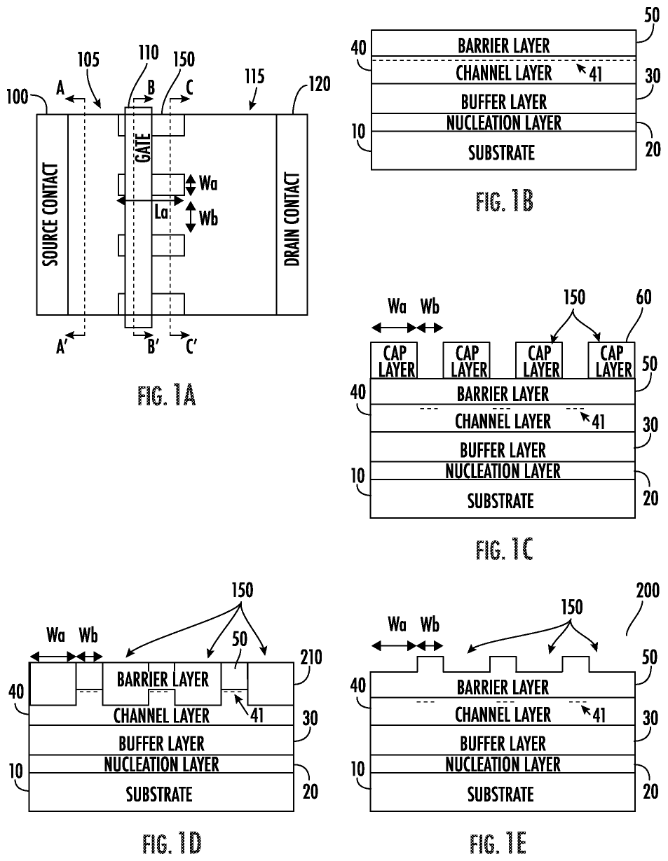

FIG. 1A shows a top view of a transistor structure 1 comprising a source contact 100, a gate electrode 110, and a drain contact 120. A source access region 105 is disposed between the source contact 100 and the gate electrode 110. Additionally, a drain access region 115 is disposed between the gate electrode 110 and the drain contact 120. The source contact 100 may also be an electrode. Similarly, the drain contact 120 may also be an electrode. These electrodes may be made of material selected from titanium, aluminum, titanium nitride, tungsten, tungsten nitride, nickel, gold, copper, platinum, molybdenum, and any other suitable conductive material or combination of conductive materials. The source contact 100 and the drain contact 120 form ohmic contacts to the barrier layer 50.

As shown in FIG. 1A, one or more electron density reduction regions, or EDR regions 150 are shown. Each of these regions may also be referred to as region-a. These EDR regions 150 may have a length of La, a width of Wa and separation distance of Wb. In this disclosure, length is defined as the direction from the source contact 100 to the drain contact 120. Width is the direction perpendicular to the length. Further, the EDR regions 150 are located in the gate region, so as to extend beneath the gate electrode 110. In some embodiments, the EDR regions 150 extend under the entire length of the gate electrode 110. In some embodiments, the EDR regions 150 may not extend under the entire length of the gate electrode 110. In certain embodiments, the EDR regions 150 extend at least 25% of the length of the gate electrode 110. In certain embodiments, the EDR regions 150 extend at least 50% of the length of the gate electrode 110. In certain embodiments, the EDR regions 150 extend at least 75% of the length of the gate electrode 110. In certain embodiments, the EDR regions 150 may extend into the source access region 105. In certain embodiments, the EDR regions 150 may extend into the drain access region 115. In certain embodiments, the EDR regions 150 extend beyond the gate electrode 110 in both directions.

The length of the EDR regions 150, La, and the width of the EDR regions 150, Wa, range from 10 nm to 50 um. The separation between adjacent EDR regions 150, Wb, ranges from 10 nm to over 50 um. The ratio, Wb/(Wa+Wb), ranges from 5% to 95%. The edges of the EDR regions 150 may or may not be aligned with III-nitride crystalline planes.

The existence of the EDR regions 150 reduces the channel electron density in these regions relative to the gate region outside the EDR regions 150 when the transistor is turned on. The channel electron density in the EDR regions 150 can be as low as zero when the gate electrode 110 is floating or is at the same voltage as the source contact 100. The gate electrode 110 is disposed above the EDR regions 150 and overlaps at least a part of EDC region 150. In FIG. 1A, the length of the gate electrode 110 is smaller than the length of EDR regions 150, La. In another embodiment, the length of the gate electrode 110 is larger than the length of EDR region 150, covering the entire EDR region 150 underneath the gate electrode 110. The position of the gate electrode 110 relative to the length of EDR region 150 can be centered, closer to the source side edge, or closer to the drain-side edge of the EDR region 150. In another embodiment, the gate electrode 110 covers the source side edges of the EDR region 150 while the drain side edges of the EDR regions extend beyond the gate electrode 110.

Although the EDR regions 150 in FIG. 1A have a rectangular shape, they may be formed in round, hexagon, oval, triangle or other shapes as well.

FIG. 1B shows the cross-section of the III-nitride semiconductor transistor structure 1 along the cutline A-A′. The transistor structure 1 comprises a substrate 10, which may be made of Si, SiC, Sapphire, III-nitride semiconductor or any other suitable material.

In some embodiments, the semiconductor transistor structure 1 may include a nucleation layer 20, formed on the substrate 10. The nucleation layer 20 may include AlN.

A buffer layer 30 is formed over the nucleation layer 20. The buffer layer 30 may have a thickness between 0.5 nm and several microns. A channel layer 40 is formed over the buffer layer 30. The buffer layer 30 and channel layer 40 comprise III-nitride semiconductors including GaN, AlGaN, InGaN, InAlN, InAlGaN and AlN. Free electrons 41 exist in the channel layer 40 to conduct electrical current between the drain contact 120 and the source contact 100. The channel layer 40 may comprise a single layer such as a GaN layer, or multiple layers. In one example, the channel layer 40 comprises a back-barrier structure, such as a GaN layer over an AlGaN layer (GaN/AlGaN) or a GaN layer over an InGaN layer and another GaN layer (GaN/InGaN/GaN). In another example, the channel layer 40 has a superlattice structure formed by repeating a bi-layer structure of AlGaN/GaN or AlN/GaN. The thickness of the channel layer 40 may be 5 nm, although other thicknesses may be used. The thickness of the buffer layer 30 may be between zero and a few microns, although other thicknesses are within the scope of the disclosure.

A barrier layer 50 is formed over the channel layer 40. The barrier layer 50 is made of III-nitride semiconductors selected from AlGaN, InAlN, AlN or InAlGaN. The barrier layer 50 may optionally also have a top layer made of III-nitride semiconductors including GaN, AlGaN, InGaN, InAlGaN.

The barrier layer may have sub-layers such as AlGaN/AlN where AlN layer is in contact with the channel layer 40 or GaN/AlGaN where AlGaN is in contact with the channel layer 40. The sub-layer of the barrier layer 50 in direct contact with the channel layer has a wider band gap than the channel layer 40 to form a heterostructure. The barrier layer 50 may be un-doped, doped with Si or other impurities. The doping density may have a delta-doping or uniform doping profile inside a sub-layer of the barrier layer 50.

The III-nitride semiconductor transistor structure may be formed with Gallium-face or Nitrogen-face III-nitride semiconductors.

As shown in FIG. 1B, two-dimensional electron gas (2DEG) 41 is formed in the channel layer 40 near the interface between the barrier layer 50 and the channel layer 40. Source contact 100 and drain contact 120 are formed at both sides of the gate electrode 110, making electrical contact to the 2DEG 41 through the barrier layer 50. In another example, instead of 2DEG, a three-dimensional electron gas is formed in the channel layer 40, with a distribution having a depth between 1 and 100 nm.

FIGS. 1C-1E illustrate three different implementations of the EDR regions 150.

In FIG. 1C, the EDR region 150 is formed by disposing a cap layer 60 over the barrier layer 50, wherein the cap layer 60 reduces or depletes the free electrons 41 in the channel layer 40 beneath the cap layer 60. In one embodiment, the 2DEG 41 only exists in the channel layer 40 where the cap layer 60 is absent. In another embodiment, the 2DEG underneath the cap layer 60 has a lower density than the channel regions outside the cap layer 60. The cap layer 60 may include III-nitride semiconductors including GaN, AlGaN, InGaN or InAlGaN. The cap layer may be doped with Mg with a doping density between 1E17/cm³ and 1E20/cm³. The cap layer 60 may have a thickness from 5 nm to over 200 nm. The cap layer 60 may be formed using deposition or another suitable method.

In FIG. 1D, the EDR region 150 is formed by ion implantation that lowers or eliminates the free electrons 41 in the channel layer 40 in the implanted region 210. The implantation may be formed by ion implantation or plasma treatment. The species used for the ion implantation may be selected from hydrogen, nitrogen, argon, fluorine, magnesium or any other suitable element. In certain embodiments, the energy of the implant may be selected so that the implanted region 210 extends through the entire thickness of the barrier layer 50. In certain embodiments, the implant energy is sufficient so that the implanted region 210 extends into the channel layer 40. In other embodiments, the implantation depth may be less than the thickness of the barrier layer 50. The dose may be selected to eliminate or reduce free electrons 41 near the interface between the channel layer 40 and the barrier layer 50.

In FIG. 1E, the EDR region 150 is formed by etching recesses 200 into the barrier layer 50 and optionally into the channel layer 40. The recesses 200 remove free electrons in the channel layer 40. This is because electrons travel at the interface between the barrier layer 50 and the channel layer 40. By etching into the barrier layer 50, the area that is used to transport electrons is reduced. In some embodiments, the recesses 200 may be etched so as to remove an entire thickness of the barrier layer 50 in the EDR regions 150. In this way, the interface between the barrier layer 50 and the channel layer 40 in the EDR regions 150 is eliminated. In certain embodiments, the recesses 200 extends into the channel layer 40. In other embodiments, the recesses 200 do not extend through the entirety of the barrier layer 50. Thus, the depth of the recesses 200 may be less than, the same as or greater than a thickness of the barrier layer 50. The recesses 200 may be created using any etching process.

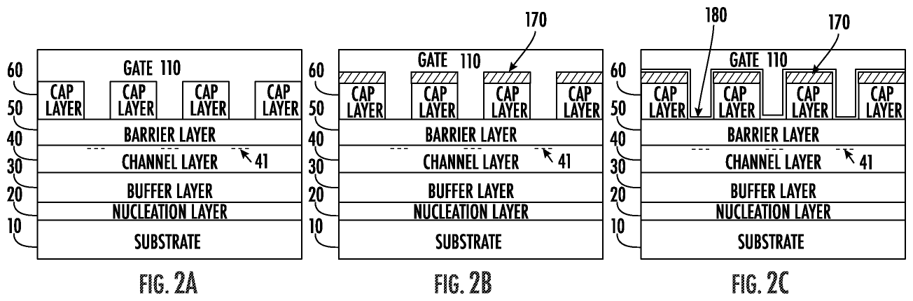

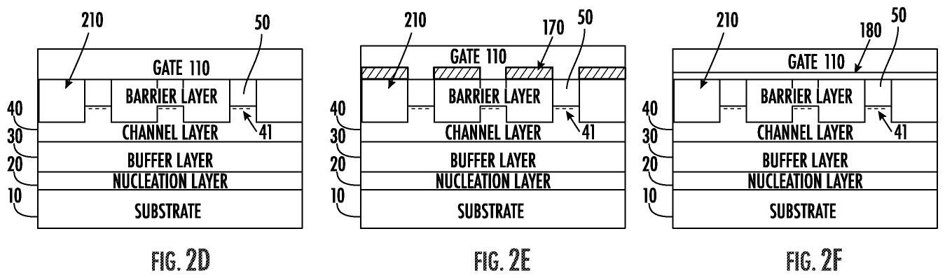

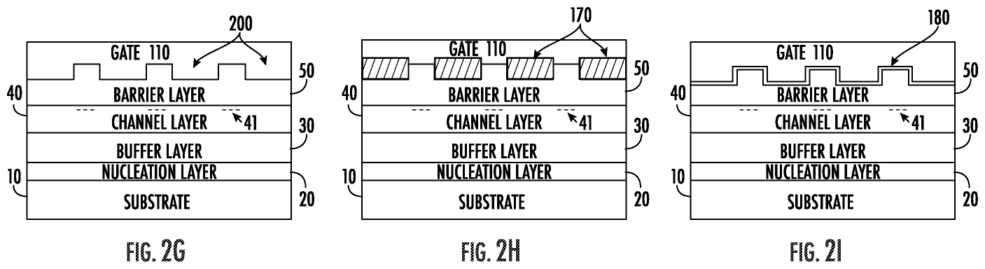

FIGS. 2A-2I show various cross-sections of the transistor structure shown in FIG. 1A along cutline B-B′. FIGS. 2A-2C are cross-sections of FIG. 1A along line B-B′ according to different embodiments, where the EDR regions 150 are as shown in FIG. 1C. FIGS. 2D-2F are cross-sections of FIG. 1A along line B-B′ according to different embodiments, where the EDR regions 150 are as shown in FIG. 1D. FIGS. 2G-2I are cross-sections of FIG. 1A along line B-B′ according to different embodiments, where the EDR regions 150 are as shown in FIG. 1E. Although the top surface of the gate electrode 110 is shown as being flat, it is understood that the top surface of the gate electrode 110 may not be flat. In many cases, the top surface of the gate electrode 110 has bumps caused by the underlying non-even surfaces.

The transistor structure shown in the figures is a normally-on transistor with free-electrons underneath the gate electrode 110 without any applied gate voltage. To turn off the normally-on transistor, a negative gate bias voltage is needed to deplete the 2DEG 41 underneath the gate electrode 110. The transistor structure may be an enhancement-mode transistor where a positive gate voltage is needed to turn on the channel underneath the gate electrode 110. One example of the enhancement-mode transistor has additional recess regions in the barrier layer 50 underneath the gate electrode 110 and outside the EDR regions 150. This additional recess makes the 2DEG 41 absent underneath the gate electrode 110 when there is no gate voltage applied. When the transistor is an enhancement-mode transistor, the electron density underneath the gate electrode 110 in the EDR region 150 is still lower than the electron density underneath the gate electrode 110 outside of the EDR region 150 when positive gate bias is applied.

As noted above, FIGS. 2A-2C represent various cross-sections of FIG. 1A along line B-B′ according to different embodiments, where the EDR regions are created by disposed a cap layer 60 on the barrier layer 50.

FIG. 2A shows an embodiment where the gate electrode 110 forms a Schottky contact to the barrier layer 50 where the cap layer 60 is absent. The gate electrode 110 may also make electrical contact to the cap layer 60 as shown in FIG. 2A.

FIG. 2B shows another embodiment where a dielectric layer 170 covers at least a portion of the cap layer 60 and the gate electrode 110 makes Schottky contact to the barrier layer 50 where the cap layer 60 is absent. As shown in FIG. 2B, the gate electrode 110 may still make electrical contact directly to the cap layer 60 via the exposed sidewall or any exposed surface of the cap layer 60. The dielectric layer 170 may be SiO₂, SiₓN_{y}, SiOₓN_{y}, Al₂O₃, another suitable dielectric material or a combination thereof. The thickness of the dielectric layer 170 may be 1 nm or more.

FIG. 2C shows an embodiment based on FIG. 2B. In this embodiment, a gate dielectric layer 180 is formed between the gate electrode 110 and the top surface of the barrier layer 50 and the dielectric layer 170. In another embodiment, the gate dielectric layer 180 may be formed over the cap layer 60 and the dielectric layer 170 may be omitted. Thus, in both embodiments, the gate dielectric layer 180 is disposed on the barrier layer 50 and above the EDR regions 150. The gate dielectric layer 180 is selected from material including SiO₂, SiₓN_{y}, SiOₓN_{y}, Al₂O₃, HfO₂, any other suitable dielectric material or a combination thereof. The thickness of the gate dielectric layer 180 may be between 1 nm and 100 nm.

As noted above, FIGS. 2D-2F represent various cross-sections of FIG. 1A along line B-B′ according to different embodiments, where the EDR regions 150 are created by implanted regions 210.

FIG. 2D shows an embodiment where the gate electrode 110 forms a Schottky contact to the barrier layer 50 in all areas, including the implanted regions 210.

FIG. 2E shows another embodiment where a dielectric layer 170 covers at least a portion of the implanted regions 210 and the gate electrode 110 makes Schottky contact to the barrier layer 50 where the barrier layer 50 is not implanted. As shown in FIG. 2E, the gate electrode 110 may still make electrical contact directly to the implanted regions 210 via any exposed surface of the implanted regions 210. The dielectric layer 170 may be SiO₂, SiₓN_{y}, SiOₓN_{y}, Al₂O₃, another suitable dielectric material or a combination thereof. The thickness of the dielectric layer 170 may be 1 nm or more.

FIG. 2F shows an embodiment where a gate dielectric layer 180 is formed between the gate electrode 110 and the top surface of the barrier layer 50, including both the implanted regions 210 and the regions that are not implanted. The gate dielectric layer 180 is selected from material including SiO₂, SiₓN_{y}, SiOₓN_{y}, Al₂O₃, HfO₂, any other suitable dielectric material or a combination thereof. The thickness of the gate dielectric layer 180 may be between 1 nm and 100 nm.

As noted above, FIGS. 2G-2I represent various cross-sections of FIG. 1A along line B-B′ according to different embodiments, where the EDR regions are created using recesses 200.

FIG. 2G shows an embodiment where the gate electrode 110 forms a Schottky contact to the barrier layer 50 in all areas, including the recesses 200.

FIG. 2H shows another embodiment where a dielectric layer 170 fills at least a portion of the recesses 200 and the gate electrode 110 makes Schottky contact to the barrier layer 50 where the recesses 200 are absent. The dielectric layer 170 may be SiO₂, SiₓN_{y}, SiOₓN_{y}, Al₂O₃ and other suitable dielectric material. The thickness of the dielectric layer 170 may be 1 nm or more.

FIG. 2I shows an embodiment where a gate dielectric layer 180 is formed between the gate electrode 110 and the top surface of the barrier layer 50, including both the recesses 200 and the regions that are not recessed. The gate dielectric layer 180 is selected from material including SiO₂, SiₓN_{y}, SiOₓN_{y}, Al₂O₃, HfO₂, any other suitable dielectric material or a combination thereof. The thickness of the gate dielectric layer 180 may be between 1 nm and 100 nm.

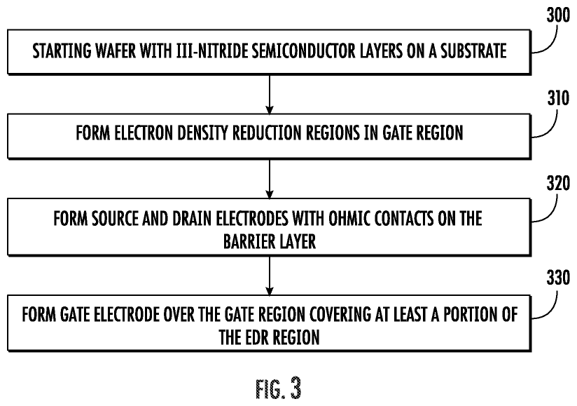

An example of fabricating the transistor structure described herein is shown in FIG. 3. First, as shown in Box 300, a wafer is provided. The wafer comprises a substrate 10, a nucleation layer 20 on top of the substrate and a buffer layer 30 disposed on the nucleation layer 20. A channel layer 40 is disposed in the buffer layer 30 and a barrier layer 50 is disposed in the channel layer.

Next, as shown in Box 310, the EDR regions 150 are formed in the wafer. As described above, this may be achieved in a number of ways.

As shown in FIG. 1C, the EDR regions 150 may be formed by depositing a cap layer 60 on the barrier layer 50. Portions of the cap layer 60, which are not part of the EDR regions 150 are then etched. The portions of the cap layer 60 that remain form the EDR regions 150.

As shown in FIG. 1D, the EDR regions 150 may be formed by implanting species into the barrier layer 50 to create implanted regions 210. These implanted regions 210 may extend into the barrier layer 50, through an entirety of the barrier layer 50 or through the barrier layer 50 and into the channel layer 40.

As shown in FIG. 1E, the EDR regions 150 may be formed by etching portions of the barrier layer 50 to create recesses 200. In certain embodiments, the depth of the recesses 200 may be greater than the thickness of the barrier layer 50. In other embodiments, the depth of the recesses 200 may be equal to or less than the thickness of the barrier layer 50.

As shown in Box 320, source contact 100 and drain contact 120 are formed with ohmic contacts on the barrier layer 50.

After the EDR regions 150 have been formed, the gate electrode 110 is formed between the source contact 100 and the drain contact 120, covering at least a portion of the EDR regions 150, as shown in Box 330.

In some embodiments, a gate dielectric layer 180 may be deposited on the barrier layer 50 and the EDR regions 150 in the gate region before the gate electrode 110 is formed. In other embodiments, a dielectric layer 170 may be deposited on the EDR regions 150 in the gate region before the gate electrode 110 is formed.

The sequence of forming the gate electrode 110, the source contact 100 and drain contact 120 may be changed. For example, source contact 100 and drain contact 120 may be formed after the formation of the gate electrode 110.

Additional process steps not shown in FIG. 3 include depositing additional dielectric layers, and forming additional field plates, vias and interconnections.

The embodiments described above in the present application may have many advantages. By having an EDR region 150 in the gate region, the device gate capacitance is modified which impacts the device switching performance, such as by improving device switching speed.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A semiconductor structure for use in a III-Nitride (III-N) semiconductor device, comprising:
a channel layer;
a barrier layer, wherein electrons are formed at an interface between the channel layer and the barrier layer;
a source contact and a drain contact disposed in ohmic recesses in contact with the barrier layer;
a gate electrode disposed between the source contact and the drain contact, wherein a region under the gate electrode comprises a gate region; and
one or more electron density reduction regions disposed in the gate region, wherein electron density in the electron density reduction regions is reduced as compared to other portions of the gate region, wherein the electron density reduction regions comprise a cap layer disposed on the barrier layer, and wherein the cap layer is not disposed on the barrier layer in the other portions of the gate region, and the cap layer comprises a Mg-doped III-nitride semiconductor.

2. The semiconductor structure of claim 1, wherein each electron density reduction region has a length (La) and a width (Wa), and is separated from an adjacent electron reduction region by a separation distance (Wb), wherein a ratio of Wb/(Wa+Wb) is between 0.05 and 0.95.

3. The semiconductor structure of claim 1, wherein the gate electrode makes Schottky contact with a top surface of the barrier layer and a top surface of the cap layer.

4. The semiconductor structure of claim 1, further comprising a dielectric layer disposed on a top surface of the cap layer in the gate region;
wherein the gate electrode makes Schottky contact with a top surface of the barrier layer and contacts a top surface of the dielectric layer.

5. The semiconductor structure of claim 4, wherein the dielectric layer comprises SiO₂, SiₓN_{y}, SiOₓN_{y}, Al₂O₃ or a combination thereof.

6. The semiconductor structure of claim 1, further comprising a gate dielectric layer disposed on a top surface of the barrier layer and on a top surface of the cap layer in the gate region; wherein the gate electrode contacts the gate dielectric layer.

7. The semiconductor structure of claim 6, wherein the gate dielectric layer comprises SiO₂, SiₓN_{y}, SiOₓN_{y}, Al₂O₃, HfO₂ or a combination thereof.

8. The semiconductor structure of claim 4, further comprising a gate dielectric layer disposed on a top surface of the barrier layer and on a top surface of the dielectric layer in the gate region;
wherein the gate electrode contacts the gate dielectric layer.

9. The semiconductor structure of claim 8, wherein the gate dielectric layer comprises SiO₂, SiₓN_{y}, SiOₓN_{y}, Al₂O₃, HfO₂ or a combination thereof.

10. A semiconductor structure for use in a III-Nitride (III-N) semiconductor device, comprising:
a channel layer;
a barrier layer, wherein electrons are formed at an interface between the channel layer and the barrier layer;
a source contact and a drain contact disposed in ohmic recesses in contact with the barrier layer;
a gate electrode disposed between the source contact and the drain contact, wherein a region under the gate electrode comprises a gate region;
one or more electron density reduction regions disposed in the gate region, wherein electron density in the electron density reduction regions is reduced as compared to other portions of the gate region; wherein the electron density reduction regions comprise implanted regions in the barrier layer, wherein a depth of the implanted region is less than, the same as, or greater than a thickness of the barrier layer.

11. The semiconductor structure of claim 10, wherein the implanted regions are implanted with hydrogen, nitrogen, argon, fluorine, or magnesium.

12. The semiconductor structure of claim 10, wherein the gate electrode makes Schottky contact with a top surface of the barrier layer and a top surface of the implanted regions.

13. The semiconductor structure of claim 10, further comprising a dielectric layer disposed on a top surface of the implanted regions in the gate region;
wherein the gate electrode makes Schottky contact with a top surface of the barrier layer and contacts the dielectric layer above the implanted regions.

14. The semiconductor structure of claim 10, further comprising a gate dielectric layer disposed on a top surface of the barrier layer and a top surface of the implanted regions in the gate region;
wherein the gate electrode contacts the gate dielectric layer.

15. The semiconductor structure of claim 14, wherein the gate dielectric layer comprises SiO₂, SiₓN_{y}, SiOₓN_{y}, Al₂O₃, HfO₂ or a combination thereof.

16. A semiconductor structure for use in a III-Nitride (III-N) semiconductor device, comprising:
a channel layer;
a barrier layer, wherein electrons are formed at an interface between the channel layer and the barrier layer;
a source contact and a drain contact disposed in ohmic recesses in contact with the barrier layer;
a gate electrode disposed between the source contact and the drain contact, wherein a region under the gate electrode comprises a gate region; and
one or more electron density reduction regions disposed in the gate region, wherein electron density in the electron density reduction regions is reduced as compared to other portions of the gate region; wherein the electron density reduction regions comprise recesses wherein a depth of the recesses is less than, the same as, or greater than a thickness of the barrier layer.

17. The semiconductor structure of claim 16, wherein the gate electrode makes Schottky contact with a top surface of the barrier layer and a top surface of the recesses.

18. The semiconductor structure of claim 16, further comprising a dielectric layer disposed on a top surface of the recesses in the gate region;
wherein the gate electrode makes Schottky contact with a top surface of the barrier layer and contacts the dielectric layer above the recesses.

19. The semiconductor structure of claim 16, further comprising a gate dielectric layer disposed on a top surface of the barrier layer and above the recesses in the gate region;
wherein the gate electrode contacts the gate dielectric layer.

20. The semiconductor structure of claim 19, wherein the gate dielectric layer comprises SiO₂, SiₓN_{y}, SiOₓN_{y}, Al₂O₃, HfO₂, or a combination thereof.
